(19) United States
(12) Patent Application Publication
(10) Pub. No.: US 2025/0331144 A1
(43) Pub. Date: Oct. 23, 2025

(54) Content Addressable Memory Cells

(71) Applicant: Taiwan Semiconductor Manufacturing Company, Ltd., Hsinchu (TW)

(72) Inventors: Huai-Ying Huang, Hsinchu (TW); Yu-Ming Lin, Hsinchu (TW)

(21) Appl. No.: 18/642,992

(22) Filed: Apr. 23, 2024

(51) Int. Cl. H10B 10/00; H01L 23/522; H01L 29/66; H10B 80/00

(52) U.S. Cl. CPC H10B 10/12; H01L 23/5226; H10B 10/18; H10B 80/00; H10D 99/00

(57) ABSTRACT

Embodiments described herein relate to content addressable memory (CAM). An example CAM device comprises a back-end-of-line (BEOL) layer that is disposed over a front-end-of-line layer. A plurality of CAM cells are provided in the device, wherein each cell comprises a storage portion and a compare portion. In the example CAM device, the storage portion of each cell of the plurality of CAM cells is disposed in the FEOL layer and the compare portion of each cell of the plurality of CAM cells is disposed in the BEOL layer.

### BACKGROUND

Modern computer and electronic devices often include memory for storing electronic data. To meet demand for smaller and faster devices various techniques and architectures, such as content addressable memory (CAM), have been developed. CAM is a type of memory that is useful in applications requiring high speed operations due to its capability for completing a search operation in a single clock cycle. In artificial intelligence (AI) applications, data sets are often large and represented by long vectors. As such, moving this data from memory to an external processor for calculations can be time consuming. Computing-in-memory (CIM) techniques, which perform calculations in memory rather than moving data to a processor, have been developed to speed up this process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a circuit diagram depicting a CAM cell according to an embodiment.

FIG. 2 is a circuit diagrams depicting a CAM array according to an embodiment.

FIG. 3 is a schematic diagram depicting a memory device according to an embodiment.

FIG. 4 is a schematic diagram depicting a connection scheme of CAM cells according to an embodiment.

FIG. 5 is a schematic diagram showing a perspective view of a memory device according to an embodiment.

FIG. 6A and FIG. 6B are cross-sectional views depicting a memory device according to an embodiment.

FIG. 7 is a flowchart depicting a method of fabricating a memory device according to an embodiment.

FIGS. 8A-8C schematic diagrams depicting cross-sectional intermediate views of a method of fabricating a memory device in accordance with an embodiment.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

As described above, content addressable memory (CAM) is a type of memory that may enable search performance in one clock cycle. CAM devices may allow for data to be accessed by searching for the content of the data, rather than by searching for an address. A search operation using CAM may take content as an input and retrieve an address of stored data that matches the input search. CAM may compare the input search against data stored in a table of memory locations and returns an output address that corresponds with the input search data.

Because it can perform a search in one clock cycle, CAM is often implemented in a variety of high speed applications such as in network switches and routers. In these systems, CAM may be used to quickly route signals or packets to a correct destination. For example, a network may transfer information via individual packets of data. To properly route a data packet to its proper destination, a router may use CAM to compare a designated destination address of an individual data packet against all of the different possible destination addresses in order to match the packet with its destination.

A CAM device may comprise a plurality of unit cells (CAM cells) arranged in an array. In embodiments described herein, CAM cells may comprise a plurality of transistors arranged so as to enable the cell to perform logic operations such as an exclusion or (XOR) to search for particular content. Each unit cell may comprise a storage portion comprising a static random access memory (SRAM) structure and configured to store data, and a compare portion configured to compare an input signal against the storage portion. In a search operation using CAM, this structure may enable a bit by bit comparison between input data and stored data. This comparison may occur simultaneously through all memory cells of an array of CAM cells, thereby allowing a complete search to be performed in a single clock cycle.

Though CAM can achieve this high operating speed, implementing this technique can be area-expensive, requiring forming a high number of transistors in a front-end-of-line (FEOL) process. To overcome this issue, embodiments described herein provide a hybrid CAM cell structure based on oxide semiconductor transistors. CAM cells described herein may comprise a 3D stack structure that reduced the FEOL footprint of the cells. For example, a CAM cell may comprise a first portion disposed in a FEOL layer and a second portion disposed in a back-end-of-line (BEOL) layer. By incorporating such a structure, CAM cells described herein may avoid occupying expensive FEOL real-estate, saving significant area cost. Additionally, embodiments described herein may achieve lower standby leakage without sacrificing performance.

Embodiments described herein may further comprise computing-in-memory (CIM) structures, devices, or systems that enable CIM operations. In these devices, calculations may be performed within a memory cell array rather than requiring the time consuming process of transporting data from memory to dedicated processing circuitry for performing the calculations. In some embodiments, a memory device may comprise a plurality of CAM cells as described above arranged in an array and configured to perform CIM operations. Such a device may enable high-speed calculations and data processing.

Owing in part to these advantages, CAM cells described herein may be used as a solution to speed up computations and reduce power consumption in artificial intelligence (AI) systems and applications. For example, AI systems, such as an artificial neural network, may involve data represented by very long vectors (in some cases greater than 1000 bits). These systems may employ mathematical operations to manipulate these long vectors and produce weighted output values or arrays which are used by the AI system to make accurate predictions. By providing CAM configured for CIM operations, embodiment of the present application may speed up the computation of such mathematical operations thereby improving the efficiency and performance of an AI system.

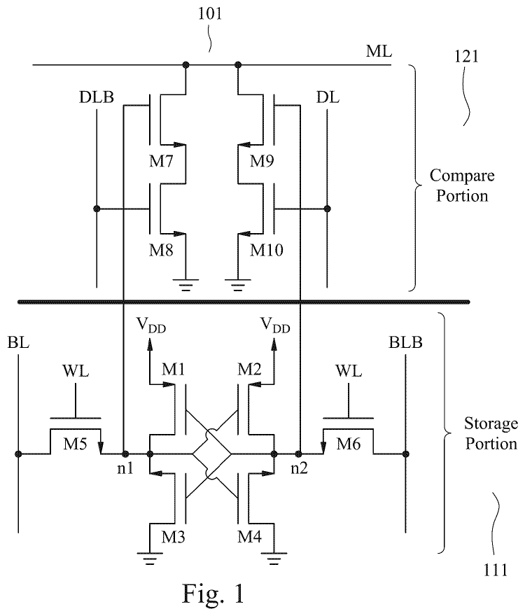

FIG. 1 is a circuit diagram depicting a CAM cell according to an embodiment. A CAM cell 101 may comprise storage portion 111 and compare portion 121. The storage portion 111 may be disposed in a FEOL layer of a device incorporating CAM cell 101, whereas compare portion 121 may be disposed in a BEOL layer of the device. In an embodiment, the storage portion 111 may comprise an SRAM structure.

In operation, storage portion 111 may be configured to store data, and compare portion 121 may be configured to compare input data against the data stored by storage portion 111. The comparison performed by compare portion 121 may comprise an exclusion or (XOR) logic operation. A result of this comparison may be output from the cell via a match line ML. As described in greater detail below, this result may be combined with results from other CAM cells in an array to generate a result for a search operation.

CAM cell 101 may comprise a binary cam cell (BCAM) having a ten transistor (10T) structure. The BCAM cell may be configured to store two possible values, “0,” or “1,” based on the results of the comparison For example, CAM cell 101 may comprise a 6T SRAM cell and four transistors in compare portion 121. The storage portion 111 may comprise the 6T SRAM cell through the arrangement of transistors M1, M2, M3, M4, M5, and M6. Nodes n1 and n2 of the storage portion 111 may store a data value of either “0” or “1.”

In an embodiment, transistors M1 and M2 may be p-type metal oxide semiconductor (PMOS) transistors each having a first source/drain connected to a first reference voltage VDD. Transistors M3 and M4 may comprise n-type metal oxide semiconductor (NMOS) transistors each having a first source/drain connected to a ground voltage.

Transistor M5 may comprise a NMOS transistor and have a first source/drain connected to a first bit line BL and a gate connected to a word line WL. A second source/drain of transistor M5 may be connected to first node n1. Transistor M6 may also comprise a NMOS transistor having a first source/drain connected to a second bit line BLB and a gate connected to the word line WL. Transistor M6 may have a second source/drain connected to second node n1.

In an embodiment, transistors M1-M6 may comprise transistors having silicon channels. Further, transistors M1-M6 may comprise high-k metal gate (HK/MG) transistors. These transistors may incorporate a high-k gate dielectric which may provide reduced leakage current. For example, the high-k dielectric may comprise hafnium oxide (HFO₂), zirconium oxide (ZrO), aluminum oxide (Al₂O₃), silicon oxynitride (SiON), hafnium dioxide-alumina alloy (HfO₂:Al₂O₃), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), another suitable high-k material, or a combination thereof. Transistors M1-M6 may also comprise gate electrodes comprising metal gate structures which may allow for precise tuning of the transistor turn-on voltage. In some embodiments, the materials of the gate electrodes may comprise one or more of aluminum (Al), copper (Cu), tungsten (W), titanium (Ti), tantalum (Ta), or alloys thereof.

Compare portion 121 of CAM cell 101 may comprise four additional transistors M7, M8, M9, and M10. Transistors M7-M10 may comprises transistors having oxide semiconductor channels. The materials used for transistors M7-M10 may be selected so as to allow for these transistors to be formed during BEOL processing without damaging components formed in the FEOL process. For example, channels of transistors M7-M10 of the compare portion may comprise oxide semiconductor materials that may be processed at low temperatures that will not damage previously fabricated devices in the FEOL layer. As described above, transistors M1-M6 may comprise a silicon channel. Accordingly, a channel material of transistors M7-M10 may comprise an oxide semiconductor material that is capable of being processed at a temperature that will not damage the silicon channel material of the FEOL transistors, or damage any other devices of the FEOL layer.

The channels of transistors M7-M10 may comprise zinc oxide (ZnO), indium tungsten oxide (InWO), indium gallium zinc oxide (InGaZnO), indium zinc oxide (InZnO), indium gallium zinc tin oxide (InGaZnSnO or IGZTO), indium tin oxide (InSnO or ITO), combinations thereof, or the like. Other oxide semiconductor materials may be used for these channel layers without departing from the scope of this disclosure. Similar to transistors M1-M6, transistors M7-M10 may also comprise high-K, metal gate structures.

Transistors M7 and M8 may comprise NMOS transistors each having a first source/drain connected to match line ML. Gates transistors M7 and M9 may be connected to first node n1 and second node n2 respectively. Accordingly, during operation, an output voltage of match line ML may result from an XOR operation between input data from a search and the state of the nodes of storage portion 111. Transistors M8 and M10 may also comprise NMOS transistors having first source/drains connected to ground voltage and gate connected to first and second digit lines DLB and DL.

It is noted that while FIG. 1 depicts a CAM cell 101 comprising a binary cam cell (BCAM) having a ten transistor (10T) structure, embodiments described herein are not so limited. For example, in another embodiment, CAM cell 101 may a ternary CAM (TCAM) cell. Unlike a binary CAM (BCAM) cell, which may be configured to store only two possible values (“0” or “1”), a TCAM cell may be configured to store one of three possible values: “0,” “1,” or “X.” The value “X” may be a “don't care” value that represents both “0” and “1.” This means that during a search operation, a stored “X” value may result in a match regardless of whether the input data comprises a “1” or a “0.” This may be useful in certain high-speed routing operations where there may be multiple destinations that would result in successful routing of an input packet.

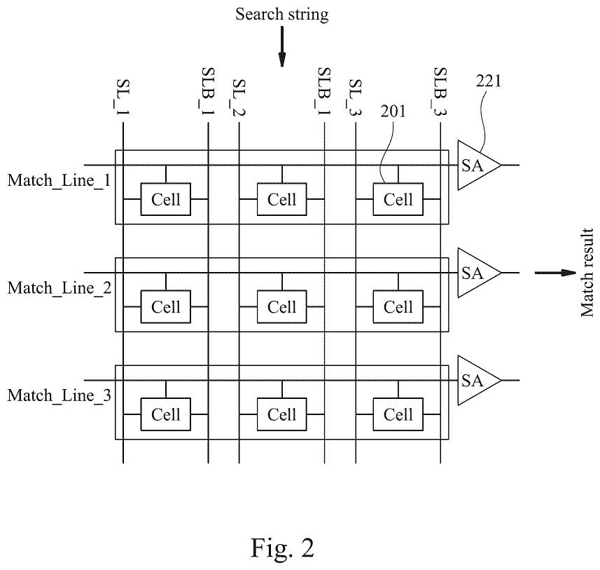

FIG. 2 is a circuit diagram depicting a CAM array according to an embodiment. FIG. 2 shows a plurality of CAM cells 201 along with connections to voltage lines depicted in the compare portion of a CAM cell as described above with reference to FIG. 1. In an embodiment, these lines may enable a search operation by the CAM array. The CAM array may comprise a plurality of CAM cells 201, wherein each CAM cell comprises a CAM cell as described above in reference to FIG. 1. Accordingly, each cell of the CAM array may comprise an storage portion disposed in a FEOL layer of a device or package and a compare portion disposed in a BEOL layer of the device or package.

In am embodiment, each cell may be connected to a match line (Match Line 1, Match, Line 2, Match Line 3, etc.) and connected between a pair of select lines (SL_1, SLB_1; SL_2, SLB_2; SL_3, SLB_3, etc.). The select lines for each cell 201 may correspond with digit lines DL and DLB as described above with respect to FIG. 1.

Each match line may be connected to a sense amplifier 221. In some embodiments, sense amplifiers 221 may further connect to an encoder which may take the results of a search through a CAM array and output a destination based on those results. Similarly, the select lines may be connected to an address decoder which, during a search operation, translates an input search into binary data that that can be compared against the stored data of the CAM array.

In addition to search operations, CAM arrays according to embodiments herein may be configured to perform CIM operations to speed up AI processing. In an embodiment, these operations may be enabled by the bit line and word line connections to each CAM cell as shown and described above with reference to FIG. 1, in addition to the connections shown in FIG. 2. For example, the data stored in each memory cell may correlate to weight data to be used in computations for an AI system. The CIM operations enabled by the CAM array may comprise mathematical operations, logic operations, or combinations thereof. The CAM array may be configured such that individual rows or columns of the array contribute weight values that are applied to input data along with CIM operations to generate weighted output data. This output data may be used by the AI system to make accurate predictions.

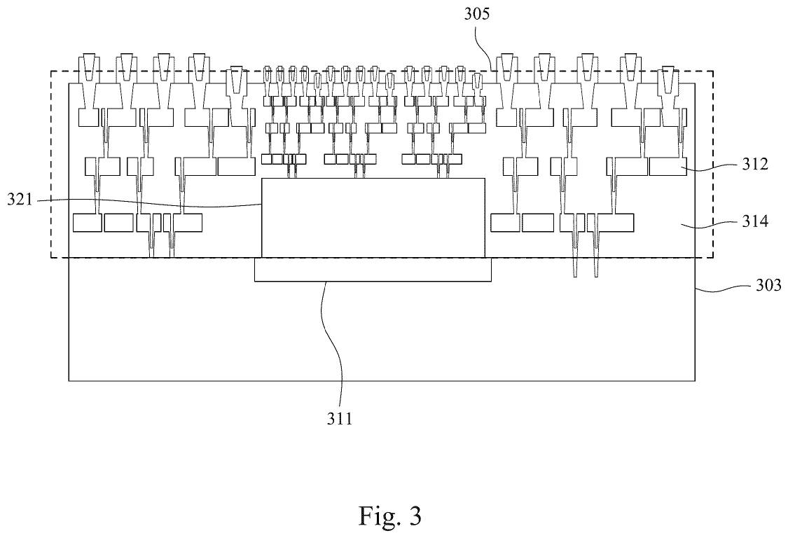

As described above, in order to implement such a CAM array in an area-efficient manner, CAM cells according to embodiments herein may comprise a 3D structure with some components formed in a FEOL layer and other components formed in a BEOL. FIG. 3 is schematic diagram depicting a memory device having such a structure according to an embodiment. The memory device may comprise a FEOL layer 303 and a BEOL layer 305. In an embodiment, storage portions of CAM cells of the memory device 311 my be disposed within the FEOL layer 303 and compare portions of CAM cells of the memory device 321 may be disposed within BEOL layer 305. The BEOL layer may further comprise a BEOL interlayer dielectric 314 and a BEOL metallization structure 312.

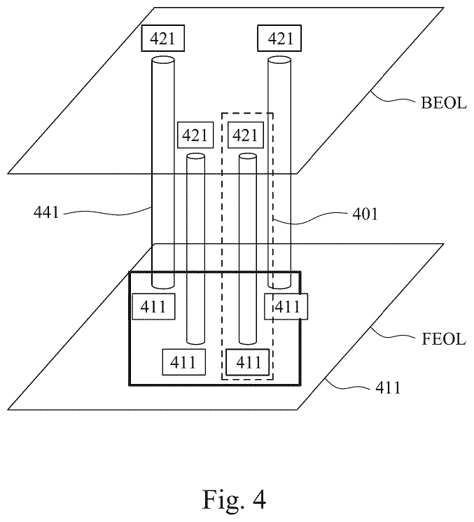

FIG. 4 is a schematic diagram depicting a connection scheme of CAM cells according to an embodiment. The FEOL layer may comprise a plurality of storage portions 411 and the BEOL layer may comprise a plurality of corresponding compare portion 421 that may be connected with a correspond storage portion 411 so as to form a CAM cell 401. This connection may be formed through conductive vias 441. Accordingly, a plurality of CAM cells may be formed by connecting each storage portion in the FEOL structure to a corresponding compare portion in the BEOL structure with a conductive via 441. Conductive vias 441 may comprise a conductive metal and the connection between a single storage portion 411 and a single compare portion 421 may further comprise metal routing layers or other connection structures in addition to the conductive via. Forming CAM cells in this manner may reduce the FEOL area used by up to 40%.

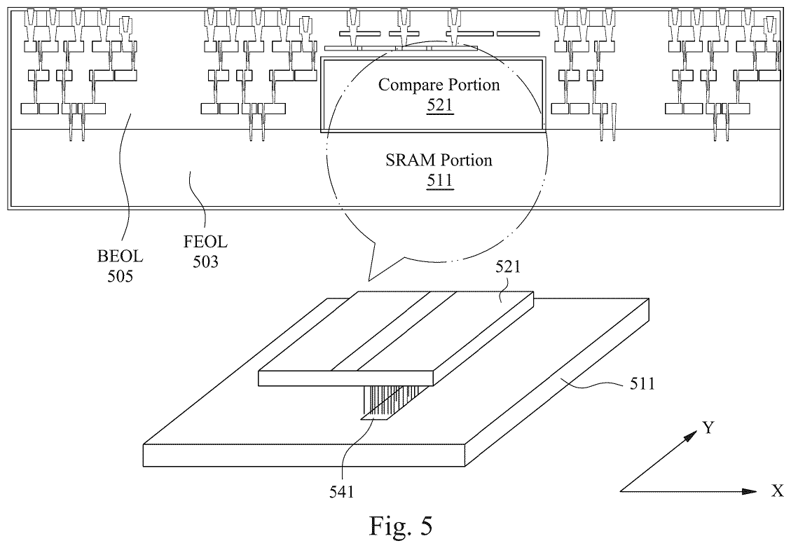

FIG. 5 is a schematic diagram showing a perspective view of a memory device according to an embodiment. FIG. 5 depicts a 3D memory device structure similar to that described above with respect to FIGS. 3-4. In an embodiment, a memory device may comprise CAM cells including storage portions 511 disposed within an FEOL layer 503 and compare portions 521 disposed within a BEOL layer. The compare portions and storage portions may be connected though conductive vias and metallization. As shown in the blown-up perspective view of FIG. 5, a plurality of conductive vias 541 may be used to connect the compare portions 521 and storage portions 521 of the CAM array, thereby forming CAM cells of the array. The transistors making up compare portions of CAM cells described herein are described in greater detail below.

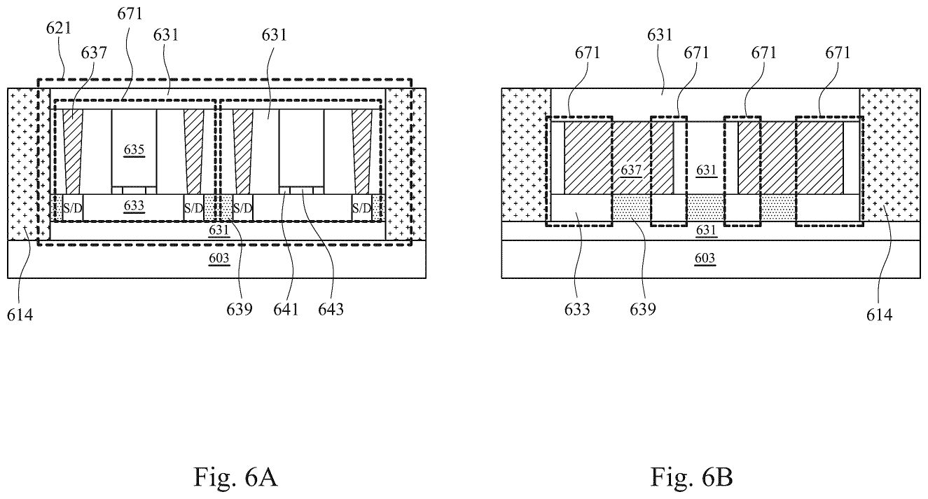

FIGS. 6A and 6B are cross-sectional views depicting a memory device according to an embodiment. FIG. 6A depicts a first cross-sectional view along a first cut of a memory device according to an embodiment and FIG. 6B depicts a second cross-sectional view along a perpendicular cut of the memory device. For example, FIG. 6A may depict a cross-section along the X-direction as shown by the axis in FIG. 5, whereas FIG. 6B may depict a cross-section along the Y-direction as shown by the axis in FIG. 5. The following description is made in reference to both FIGS. 6A and 6B.

In an embodiment, a memory device may comprise a FEOL layer 603. The memory device may comprise a plurality of CAM cells and the FEOL lay may comprise storage portions of the plurality of CAM cells. A BEOL layer comprising BEOL metal line routing 614 may be disposed over the FEOL layer 603. BEOL metal line routing 614 may comprise any conductive metal configured to route signals through the device.

Compare portions 621 of the plurality of CAM cells may be disposed in the BEOL layer. As described above with reference to at least FIG. 1, the compare portion may comprise a plurality of transistors 671. The plurality of transistors may be separated from the FEOL layer by a first portion of an interlayer dielectric layer 631.

Each transistor 671 of the compare portions of the plurality of CAM cells may comprise a semiconductor layer 633 comprising a channel region and source/drain regions S/D. The source/drain regions may interface with interconnect structures 637 that route signals to and from the source/drain regions. Interconnect structures 637 may be formed within a second portion of interlayer dielectric 631. Individual transistors of the plurality of transistors may be separated from one another by an isolation layer 639. The isolation layer 639 may comprise an oxide layer or any other material capable of providing electrical insulation and isolation between adjacent transistors.

As described above, the semiconductor layer forming channel as well as the source/drain regions may comprise an oxide semiconductor. As non-limiting examples, the oxide semiconductor layer may comprise zinc oxide (ZnO), indium tungsten oxide (InWO), indium gallium zinc oxide (InGaZnO or IGZO), indium zinc oxide (InZnO), indium gallium zinc tin oxide (InGaZnSnO or IGZTO), indium tin oxide (InSnO or ITO), combinations thereof, or the like.

Each transistor 671 may further comprise a high-k, metal gate structure. For example each transistor may comprise a high-k gate dielectric layer 643. As non-limiting examples, the high-k gate dielectric layer may comprise hafnium oxide (HFO₂), zirconium oxide (ZrO), aluminum oxide (Al₂O₃), silicon oxynitride (SiON), hafnium dioxide-alumina alloy (HfO₂:Al₂O₃), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), another suitable high-k material, a combination thereof or the like. The high-k gate dielectric layer 643 may be bounded by an interfacial layer 641 that may comprise, for example, silicon dioxide or silicon oxynitride.

Each transistor of the compare portions may further comprise a gate electrode 635 disposed over the high-k gate dielectric layer 643 and interfacial layer 641. The gate electrodes 635 may comprise metal gate including one or more of aluminum (Al), copper (Cu), tungsten (W), titanium (Ti), tantalum (Ta), or alloys thereof. Additional interlayer dielectric 631 may be formed over the gate electrode 635 and interconnects 637. Metal routing layers may be formed in this dielectric so as to route signals to and from the interconnects and the gate electrodes of the CAM array.

As shown in FIG. 6B, the plurality of transistors of compare portions of the plurality of CAM cells may be spaced apart in the second direction. The cross-section of FIG. 6B shows a plurality of oxide semiconductor layers 633 spaced apart from one another by a plurality of isolation regions 639. In an embodiment, each oxide semiconductor layer 633 may correspond with a transistor 671. Adjacent transistors, while spaced apart by isolation regions 639, may share interconnects 637.

By forming the compare portions of CAM cells in this manner, space may be saved in the FEOL layer of a memory device. The 3D stack structure according to embodiments herein may therefore provide an area and cost efficient means of implementing high speed CAM arrays. Additionally, the transistors of the compare portions in the BEOL may comprise materials that can be formed by compatible BEOL processes, thereby mitigating risk to FEOL components during fabrication of the BEOL transistors.

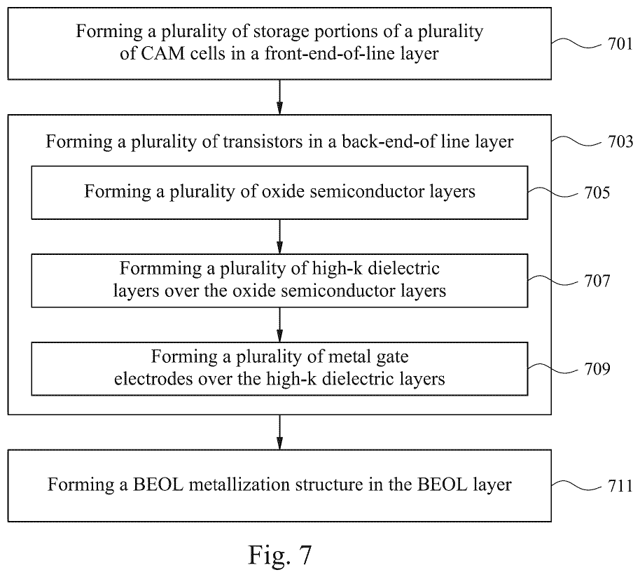

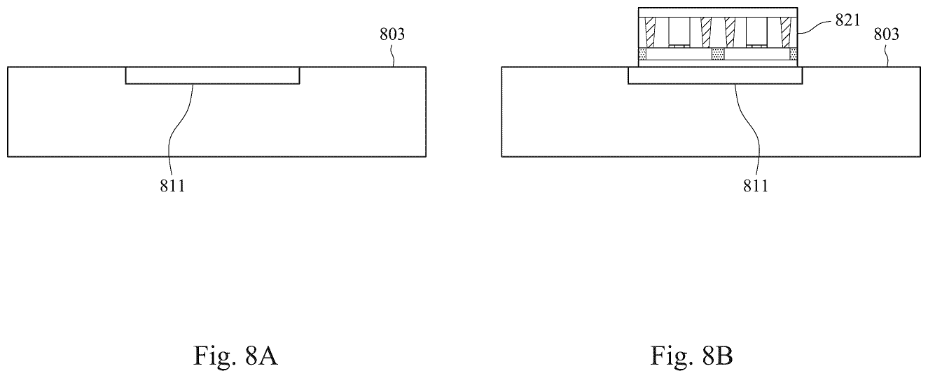

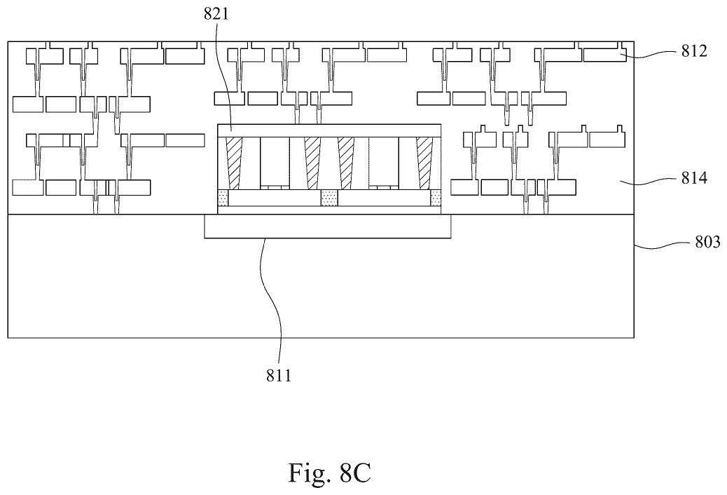

FIG. 7 is a flowchart depicting a method of fabricating a memory device according to an embodiment. FIGS. 8A-8C are schematic diagrams depicting cross-sectional intermediate views of a method of fabricating a memory device in accordance with an embodiment. An example method may comprise, at 701, forming a plurality of storage portions of a plurality of CAM cells in a front-end-of-line layer. With reference to FIG. 8A, this may comprise forming storage portions 811 in FEOL layer 803. As described above with reference to at least FIG. 1, storage portions of CAM cells according to embodiments herein may comprise a plurality of transistors formed into a SRAM structure. For example, the storage portion may comprise a 6T SRAM cell.

The method may further comprise forming a plurality of transistors in a back-end-of-line layer, as shown at 703. In an embodiment the plurality of transistors formed in the BEOL layer may comprise the compare portions of CAM cells. For example, as shown in FIG. 8B, compare portions 821 may be formed over storage portions 811 in FEOL layer 803. Forming the plurality of transistors may comprise forming a plurality of oxide semiconductor layers at 705, forming a plurality of high-k dielectric layers over the oxide semiconductor layers at 707, and forming a plurality of metal gate electrodes over the high-k dielectric layers at 709.

In some embodiments, forming the transistors of compare portions 821 may comprise performing fabrication processing directly on the FEOL layer 803. For example, forming the transistors may comprise depositing materials directly on the FEOL layer and performing further processing on the deposited materials to form transistors.

In an embodiment, this forming the plurality of oxide semiconductor layers at 705 may comprise depositing an oxide semiconductor material over the FEOL layer. The deposition processes used may be selected such that they do not negatively impact already-formed transistors and components in the FEOL layer. For example, a material of the oxide semiconductor may be selected such that deposition of the material does not occur at a temperature that would damage components of the FEOL layer. Forming the plurality of oxide semiconductor layers may further comprise etching or lithography steps to remove deposited material at undesired locations. These processes may also be selected so as to not damage the underlying materials and components. Similar processing may occur for forming the plurality of high-k dielectric layers at 707 and forming the plurality of metal gate electrodes at 709.

In other embodiments, forming the plurality of transistors in a BEOL layer at 703 may comprise pre-fabricating compare portions 821 as a compare portion component and attaching the compare portion component to the FEOL layer. For example, the plurality of transistors may be formed by similar steps of forming a plurality of oxide semiconductor layers at 705, forming a plurality of high-k dielectric layers at 707, and forming a plurality of metal gate electrodes at 709, but these processes may occur away from the FEOL layer. For example, the compare portions 821 may be formed as a chiplet. This chiplet comprising compare portions 821 may then be attached to the FEOL layer 803. The resulting structure may also look like that shown in FIG. 8B.

The method of fabricating a memory device may further comprise forming a BEOL metallization structure in the BEOL layer. For example, as shown in FIG. 8C, metal routing layers and vias making up a metallization structure 812 may be formed in the BEOL layer and may be disposed within an interlayer dielectric layer 814. The metallization structure may be formed through a build-up process comprising a plurality of interlayer dielectric layers, each comprising a series of routing layers and vias. However, the methods described herein are not so limited and the metallization structure may be formed through other processes.

Devices, memory cells, and methods are described herein. In an example device, a back-end-of-line (BEOL) layer is disposed over a front-end-of-line layer. A plurality of content addressable memory (CAM) cells are provided wherein each cell comprises a storage portion and a compare portion. In the memory device, the storage portion of each cell of the plurality of CAM cells is disposed in the FEOL layer and the compare portion of each cell of the plurality of CAM cells is disposed in the BEOL layer.

In an example memory cell, a first plurality of transistors is disposed in a first layer of a memory device and configured to store a first data value and a second plurality of transistors disposed in a second layer of the memory and connected to the first plurality of transistors. The memory cell further includes a match line that is connected to the second plurality of transistors, and the second plurality of transistors is configured to output a second data value via the match line based on a comparison between an input data value and the first data value.

In an example method of fabricating a memory device, a plurality of SRAM structures are formed in a FEOL layer and a plurality of transistors are formed in a BEOL layer over the FEOL layer. Forming the plurality of transistors includes forming a plurality of oxide semiconductor layers, forming a plurality of high-k dielectric layers over the plurality of oxide semiconductor layers, and forming a plurality of metal gate electrodes over the plurality of high-k dielectric layers. The method further includes forming a BEOL metallization structure in the BEOL layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

It is claimed:

1. A memory device comprising:
a front-end-of-line (FEOL) layer and a back-end-of-line (BEOL) layer disposed over the FEOL layer; and
a plurality of content addressable memory (CAM) cells, each cell comprising a storage portion and a compare portion,
wherein the storage portion of each cell of the plurality of CAM cells is disposed in the FEOL layer and the compare portion of each cell of the plurality of CAM cells is disposed in the BEOL layer.

2. The memory device of claim 1, wherein compare portion and the storage portion comprise a 3D stack;
the storage portion comprises a first plurality of transistors comprising a static random access memory (SRAM) cell, wherein the plurality of transistors comprise a first channel material;
the compare portion comprises a second plurality of transistors, wherein the second plurality of transistors comprise a second channel material; and
the second channel material comprises a material capable of being processed at a temperature that will not damage the first channel material.

3. The memory device of claim 2, wherein the first channel material comprises silicon and the second channel material comprises an oxide semiconductor material.

4. The memory device of claim 1, wherein the compare portion of each cell comprises a plurality of transistors comprising oxide semiconductor channels.

5. The memory device of claim 4, wherein each transistor of the plurality of transistors further comprises a high-k gate dielectric and a metal gate electrode.

6. The memory device of claim 1, further comprising a plurality of conductive vias configured to connect the storage portion of each cell with the compare portion of each cell.

7. The memory device of claim 1, wherein each cell of the plurality of CAM cells is connected to a match line configured to output the result of a logic operation.

8. The memory device of claim 1, wherein the plurality of CAM cells is configured to perform computing-in-memory (CIM) operations.

9. The memory device of claim 8, wherein the CIM operations are configured to generate weighted output data and the plurality of CAM cells are figured to contribute weight values for the CIM operations.

10. An artificial intelligence system comprising the memory device of claim 1, wherein the plurality of CAM cells is configured to perform computing-in-memory (CIM) operations.

11. A memory cell comprising:
a first plurality of transistors disposed in a first layer of a memory device and configured to store a first data value;
a second plurality of transistors disposed in a second layer of the memory and connected to the first plurality of transistors; and
a match line connected to the second plurality of transistors,
wherein the second plurality of transistors is configured to output a second data value via the match line based on a comparison between an input data value and the first data value.

12. The memory cell of claim 11, wherein the first plurality of transistors comprises 6T SRAM cell.

13. The memory cell of claim 12, wherein the second plurality of transistors comprises four transistors such that the memory cell comprises a 10T binary content addressable memory (CAM) cell.

14. The memory cell of claim 11, wherein each transistor of the plurality of transistors comprises an oxide semiconductor channel.

15. The memory cell of claim 11, wherein the second layer is disposed on the first layer to form a 3D stack structure.

16. A method of fabricating a memory device comprising:
forming a plurality of SRAM structures in a front-end-of-line (FEOL) layer;
forming a plurality of transistors in a back-end-of-line (BEOL) layer over the FEOL layer, wherein forming the plurality of transistors comprises:
forming a plurality of oxide semiconductor layers;
forming a plurality of high-k dielectric layers over the plurality of oxide semiconductor layers; and
forming a plurality of metal gate electrodes over the plurality of high-k dielectric layers; and
forming a BEOL metallization structure in the BEOL layer.

17. The method of claim 16 further comprising forming a plurality of vias extending between the FEOL layer and the BEOL layer.

18. The method of claim 17, wherein the plurality of SRAM structure comprises a plurality of storage portions of a plurality of CAM cells, the plurality of transistors comprises a plurality of compare portions of a plurality of CAM cells, each CAM cell comprises a single storage portion and a single compare portion; and
a first via of the plurality of vias is configured to connect a first single storage portion of a first CAM cell with a first single compare portion of the first CAM cell.

19. The method of claim 16, wherein forming the plurality of transistors comprises directly depositing materials over the FEOL layer.

20. The method of claim 16, wherein forming the plurality of transistors comprises pre-fabricating a compare portion component and attaching the compare portion component to the FEOL layer.
